(19) United States
(12) Patent Application Publication
(10) Pub. No.: US 2026/0372192 A1
(43) Pub. Date: Nov. 19, 2026

(54) SEMICONDUCTOR DEVICES AND METHODS OF MANUFACTURE

(71) Applicant: Taiwan Semiconductor Manufacturing Co., Ltd., Hsinchu (TW)

(72) Inventors: Chen-Hua Yu, Hsinchu (TW); Tung-Liang Shao, Hsinchu (TW)

(21) Appl. No.: 19/751,966

(22) Filed: Jul. 23, 2026

Related U.S. Application Data
(62) Division of application No. 18/606,497, filed on Mar. 15, 2024.

(51) Int. Cl. H10W 90/00; H10W 70/65; H10W 74/01; H10W 74/10; H10W 72/00

(52) U.S. Cl. CPC H10W 90/00; H10W 70/65; H10W 74/014; H10W 74/117; H10W 72/0198; H10W 74/10; H10W 90/734; H10W 90/794

(57) ABSTRACT

A semiconductor device and method of manufacture are provided. In embodiments the method includes bonding a first die and a second die to a third die, the first die comprising a first optical device and then encapsulating the first die and the second die with an encapsulant. A bridge is bonded to the first die and the second die on an opposite side from the third die, wherein an optical component of the bridge is aligned to transmit and receive optical signals to and from the first optical device.

### PRIORITY CLAIM AND CROSS-REFERENCE

This application is a divisional of U.S. Patent Application No 18/606,497, filed Mar. 15, 2024 and entitled “Semiconductor Devices and Methods of Manufacture,” which application is hereby incorporated herein by reference.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size (e.g., shrinking the semiconductor process node towards the sub-20nm node), which allows more components to be integrated into a given area. As the demand for miniaturization, higher speed and greater bandwidth, as well as lower power consumption and latency has grown recently, there has grown a need for smaller and more creative packaging techniques of semiconductor dies.

As semiconductor and optical technologies further advance, stacked and bonded semiconductor devices and photonic dies have emerged as an effective alternative to further reduce the physical size of semiconductor devices and optical devices. In a stacked device, active circuits such as logic, memory, processor circuits and the like are fabricated at least partially on separate substrates and then physically and electrically bonded together in order to form a functional device. Such bonding processes utilize sophisticated techniques, and improvements are desired.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-4 illustrate a formation of a system on integrated chip device, in accordance with some embodiments.

FIGS. 5-6 illustrate a formation of a carrier package structure for a plurality of system on integrated chip devices, in accordance with some embodiments.

FIGS. 7-8 illustrate a formation of a functional bridge support structure, in accordance with some embodiments.

FIGS. 9-10 illustrate a formation of a first wafer scale semiconductor package, in accordance with some embodiments.

FIGS. 11-13 illustrate a formation of a second wafer scale semiconductor package, in accordance with some embodiments.

FIGS. 14-18 illustrate a formation of a third wafer scale semiconductor package, in accordance with some embodiments.

FIGS. 19-22 illustrate a formation of a fourth wafer scale semiconductor package, in accordance with some embodiments.

FIG. 23 illustrates a fifth wafer scale semiconductor package, in accordance with some embodiments.

FIG. 24 illustrates a sixth wafer scale semiconductor package, in accordance with some embodiments.

FIG. 25 illustrates a seventh wafer scale semiconductor package, in accordance with some embodiments.

FIG. 26 illustrates a fiber connection between wafer scale semiconductor packages, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will now be described with respect to semiconductor and optical devices in which an overlying element is utilized for both support as well as to optical and electrically bridge multiple devices. The embodiments presented, however, are intended to be illustrative of the presented embodiments, and are not intended to limit the embodiments in any fashion.

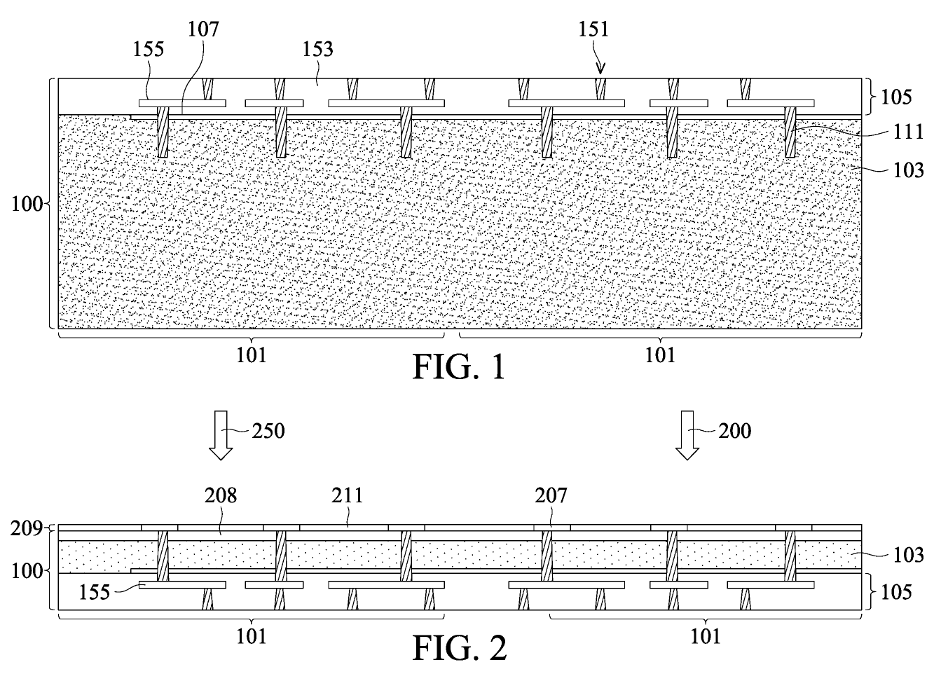

With reference now to FIG. 1, a semiconductor wafer 100 is illustrated with multiple first semiconductor device regions 101 formed within and over the semiconductor wafer 100. In a particular embodiment, the first semiconductor device regions 101 may be SRAM memory regions, DRAM memory device regions, I/O regions, logic regions, central processing unit (CPU) regions, combinations of these, or the like. Additionally, the semiconductor wafer 100 may be received by the manufacturer from a third party manufacturer, or may be manufactured in house.

In an embodiment the first semiconductor device regions 101 may comprise a first substrate 103, first active devices 107, and first metallization layers 105. The first substrate 103 may comprise bulk silicon, doped or undoped, or an active layer of a silicon-on-insulator (SOI) substrate. Generally, an SOI substrate comprises a layer of a semiconductor material such as silicon, germanium, silicon germanium, SOI, silicon germanium on insulator (SGOI), or combinations thereof. Other substrates that may be used include multi-layered substrates, gradient substrates, or hybrid orientation substrates.

The first active devices 107 comprise a wide variety of active devices and passive devices such as capacitors, resistors, inductors and the like that may be used to generate the desired structural and functional requirements of the design for the first semiconductor device regions 101. The first active devices 107 may be formed using any suitable methods either within or else on the first substrate 103.

The first metallization layers 105 are formed over the first substrate 103 and the first active devices 107 and are designed to connect the various active devices to form functional circuitry. In an embodiment the first metallization layers 105 are formed of first alternating layers of dielectric material 153 (e.g., low-k dielectric materials, extremely low-k dielectric material, ultra low-k dielectric materials, combinations of these, or the like) and first conductive structures 155 (e.g., conductive lines and vias). In an embodiment, the first metallization layers 105 may be formed through any suitable process (such as deposition, damascene, dual damascene, etc.). In an embodiment there may be four layers of metallization separated from the first substrate 103 by at least one interlayer dielectric layer (ILD), but the precise number of first metallization layers 105 is dependent upon the design of the first semiconductor device regions 101.

First through substrate vias (TSVs) 111 may be formed within the first substrate 103 and, if desired, one or more layers of the first metallization layers 105, in order to provide electrical connectivity from a front side of the first substrate 103 to a backside of the first substrate 103. In an embodiment the first TSVs 111 may be formed by initially forming through silicon via openings into the first substrate 103 and, if desired, any of the overlying first metallization layers 105 (e.g., after the desired first metallization layer 105 has been formed but prior to formation of the next overlying first metallization layer 105). The TSV openings may be formed by applying and developing a suitable photoresist, and removing portions of the underlying materials that are exposed to a desired depth. The TSV openings may be formed so as to extend into the first substrate 103 to a depth greater than the eventual desired height of the first substrate 103. Accordingly, while the depth is dependent upon the overall designs, the depth may be between about 20 μm and about 200 μm, such as a depth of about 50 μm.

Once the TSV openings have been formed within the first substrate 103 and or any first metallization layers 105, the TSV openings may be lined with a liner. The liner may be, e.g., an oxide formed from tetraethylorthosilicate (TEOS) or silicon nitride, although any suitable dielectric material may be used. The liner may be formed using a plasma enhanced chemical vapor deposition (PECVD) process, although other suitable processes, such as physical vapor deposition or a thermal process, may be used. Additionally, the liner may be formed to a thickness of between about 0.1 μm and about 5 μm, such as about 1 μm.

Once the liner has been formed along the sidewalls and bottom of the TSV openings, a barrier layer may be formed and the remainder of the TSV openings may be filled with first conductive material. The first conductive material may comprise copper, although other suitable materials such as aluminum, alloys, doped polysilicon, combinations thereof, and the like, may be utilized. The first conductive material may be formed by electroplating copper onto a seed layer, filling and overfilling the TSV openings. Once the TSV openings have been filled, excess liner, barrier layer, seed layer, and first conductive material outside of the TSV openings may be removed through a planarization process such as chemical mechanical polishing (CMP), although any suitable removal process may be used.

FIG. 2 illustrates a thinning of the first substrate 103 along with formation of a first wafer bond layer 209. In an embodiment the first substrate 103 may be thinned in order to expose the conductive material of the first TSVs 111, and may be performed using, for example, a chemical mechanical polishing process, a grinding process, an etchback process, combinations of these, or the like. However, any suitable thinning process may be utilized.

Once the first substrate 103 has been thinned, a passivation layer 208 and the first wafer bond layer 209 may be formed. In an embodiment the passivation layer 208 may be formed by initially recessing the material of the first substrate 103 using an etching process, then depositing a dielectric material using by chemical vapor deposition, physical vapor deposition, spin-on, combinations of these, or the like. Once deposited the dielectric material may be planarized using, e.g., a chemical mechanical polishing process.

In an embodiment, the first wafer bond layer 209 may be used for dielectric-to-dielectric and metal-to-metal bonding (also referred to as hybrid bonding) or fusion bonding (also referred to as dielectric-to-dielectric or oxide-to-oxide bonding). In accordance with some embodiments, the first wafer bond layer 209 is formed of a bonding dielectric 211 and first conductive bond pads 207. In an embodiment the bonding dielectric 211 may be a silicon-containing dielectric material such as silicon oxide or the like. The bonding dielectric 211 may be deposited using any suitable method, such as, atomic layer deposition (ALD), CVD, high-density plasma chemical vapor deposition (HDPCVD), PVD. However, any suitable material, process may be utilized.

Once the bonding dielectric 211 has been formed, bond openings may be formed within the bonding dielectric 211 to prepare for the formation of the first conductive bond pads 207. In an embodiment the bond openings may be formed by first applying and patterning a photoresist over the top surface of the bonding dielectric 211. The photoresist is then used to etch the bonding dielectric 211 in order to form the openings. The bonding dielectric 211 may be etched by dry etching (e.g., reactive ion etching (RIE) or neutral beam etching (NBE)), wet etching, or the like.

Once the openings have been formed, the first conductive bond pads 207 may be formed in physical and electrical contact with the first TSVs 111. In an embodiment, the first conductive bond pads 207 may comprise an optional barrier layer, an optional seed layer, a fill metal, or combinations thereof (not separately illustrated). The barrier layer may comprise titanium, titanium nitride, tantalum, tantalum nitride, or the like. The seed layer may be a conductive material such as copper and may be blanket deposited over the barrier layer using processes such as sputtering, evaporation, or plasma-enhanced chemical vapor deposition (PECVD), or the like, depending upon the desired materials. The fill metal may be a conductor such as copper or a copper alloy and may be deposited over the seed layer to fill or overfill the openings through a plating process such as electrical or electroless plating. Once the fill metal has been deposited, excess material of the fill metal, the seed layer, and the barrier layer may be removed from outside of the openings through a planarization process such as chemical mechanical polishing. However, while a single damascene process has been described for forming the first conductive bond pads 207, any suitable method, such as a dual damascene process, may also be utilized.

However, the above described embodiment in which the bonding dielectric 211 is formed, patterned, and the first conductive bond pads 207 is plated into openings before being planarized is intended to be illustrative and is not intended to be limiting upon the embodiments. Rather, any suitable method of formation of the bonding dielectric 211 and the first conductive bond pads 207 may be utilized. In other embodiments, the first conductive bond pads 207 may be formed first using, for example, a photolithographic patterning and plating process, and then the bonding dielectric 211 is used to gap fill the area around the first conductive bond pads 207 before being planarized using a planarization process. Any such manufacturing process is fully intended to be included within the scope of the embodiments.

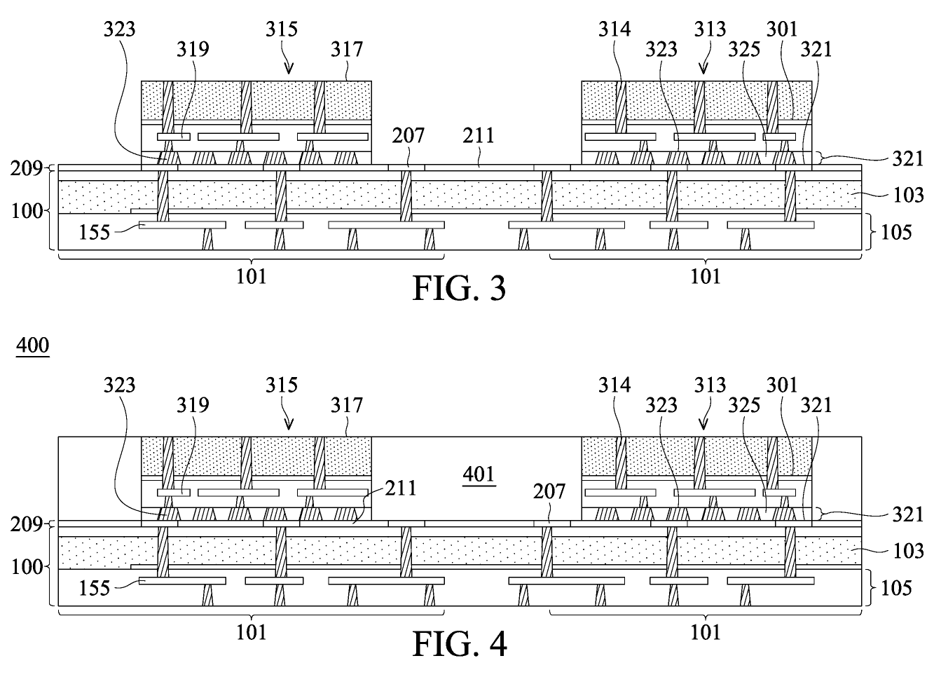

With reference now to FIG. 3, a bonding of a first semiconductor die 313 and a second semiconductor die 315 to the first conductive bond pads 207 and the first wafer bond layer 209 is performed. In an embodiment, each of the first semiconductor die 313 and the second semiconductor die 315 may each be a system on chip device, such as a logic device, which is intended to work in conjunction with the first semiconductor device regions 101. However, any suitable functionality, such as ASIC dies, central processing unit (CPU) dies, XPU dies, die to die connector dies (either standalone or merged with additional computing dies), photonic integrated circuit (PIC) dies, input/output dies, combinations of these, or the like, may be utilized. Any suitable devices may be utilized.

In an embodiment, the first semiconductor die 313 and the second semiconductor die 315 may each have second substrates 317, second active devices 301, second metallization layers 319, second TSVs 314, and second wafer bond layers 321 with second conductive bond pads 323 and a second bonding dielectric 325. In an embodiment the second substrates 317, the second active devices 301, the second metallization layers 319, the second wafer bond layers 321, the second conductive bond pads 323, the second TSVs 314 and the second bonding dielectric 325 may be formed similar to the first substrate 103, the first active devices 107, the first metallization layers 105, the TSVs 111, the first wafer bond layer 209, the first conductive bond pads 207, and the bonding dielectric 211, respectively, as discussed above. However, in other embodiments these structures may be formed using different processes and different materials.

Once the first semiconductor die 313 and the second semiconductor die 315 have been prepared, the first semiconductor die 313 and the second semiconductor die 315 are bonded to the first semiconductor device regions 101 using, for example, dielectric-to-dielectric and metal-to-metal bonding. In an embodiment the surfaces of the first semiconductor device regions 101 and the surfaces of the first semiconductor die 313 and the second semiconductor die 315 may initially be activated. Activating the top surfaces of the first semiconductor device regions 101, the first semiconductor die 313, and the second semiconductor die 315 may comprise a dry treatment, a wet treatment, a plasma treatment, exposure to an inert gas plasma, exposure to H₂, exposure to N₂, exposure to O₂, or combinations thereof, as examples. In embodiments where a wet treatment is used, an RCA cleaning may be used, for example. In another embodiment, the activation process may comprise other types of treatments. The activation process assists in the bonding of the first semiconductor device regions 101, first semiconductor die 313 and the second semiconductor die 315.

After the activation process, the first semiconductor die 313 and the second semiconductor die 315 may be placed into contact with the first semiconductor device regions 101. In a particular embodiment in which dielectric-to-dielectric and metal-to-metal bonding is utilized, the first conductive bond pads 207 are placed into physical contact with the second conductive bond pads 323 while the bonding dielectric 211 is placed into physical contact with the second bonding dielectric 325. With the activation process chemically modifying the surfaces, the bonding process between the materials is begun upon the physical contact.

Once physical contact has begun the bonding process, the bonding may then be strengthened by subjecting the assembly to a thermal treatment. In an embodiment the first semiconductor device regions 101, the first semiconductor die 313, and the second semiconductor die 315 may be subjected to a temperature between about 200°C and about 400°C to strengthen the bond. The first semiconductor device regions 101, the first semiconductor die 313, and the second semiconductor die 315 may then be subjected to a temperature at or above the eutectic point for material of the first conductive bond pads 207 and the second conductive bond pads 323. In this manner, fusion of the first semiconductor device regions 101, the first semiconductor die 313, and the second semiconductor die 315 forms a hybrid bonded device.

Additionally, while specific processes have been described to initiate and strengthen the dielectric-to-dielectric and metal-to-metal bonding between the first semiconductor device regions 101, the first semiconductor die 313, and the second semiconductor die 315, these descriptions are intended to be illustrative and are not intended to be limiting upon the embodiments. Rather, any suitable combination of baking, annealing, pressing, or other bonding processes or combination of processes may be utilized. All such processes are fully intended to be included within the scope of the embodiments.

Also, while dielectric-to-dielectric and metal-to-metal bonding has been described as one method of bonding the first semiconductor device regions 101 to the first semiconductor die 313 and the second semiconductor die 315, this as well is only intended to be illustrative and is not intended to be limiting upon the embodiments. Rather, any suitable method of bonding, such as solder bonding using, e.g., a ball grid array, may also be utilized. Any suitable method of bonding the first semiconductor device regions 101 to the first semiconductor die 313 and the second semiconductor die 315 may be utilized.

With reference now to FIG. 4, the first semiconductor die 313, the second semiconductor die 315, and the first semiconductor device regions 101 may be encapsulated with a first encapsulant 401 and singulated to form a system on integrated chip (SoIC) device 400. In an embodiment, the encapsulation may be performed in a molding device, which may comprise a top molding portion and a bottom molding portion separable from the top molding portion. When the top molding portion is lowered to be adjacent to the bottom molding portion, a molding cavity may be formed for the first semiconductor device regions 101, the first semiconductor die 313, and the second semiconductor die 315.

During the encapsulation process the top molding portion may be placed adjacent to the bottom molding portion, thereby enclosing the first semiconductor device regions 101, the first semiconductor die 313, and the second semiconductor die 315 within the molding cavity. Once enclosed, the top molding portion and the bottom molding portion may form an airtight seal in order to control the influx and outflux of gasses from the molding cavity. Once sealed, the first encapsulant 401 may be placed within the molding cavity.

The first encapsulant 401 may be an epoxy or a molding compound resin such as polyimide, polyphenylene sulfide (PPS), polyetheretherketone (PEEK), poly ether sulphone (PES), a heat resistant crystal resin, combinations of these, or the like. The first encapsulant 401 may be placed within the molding cavity prior to the alignment of the top molding portion and the bottom molding portion, or else may be injected into the molding cavity through an injection port, using compression molding, transfer molding, or the like.

Once the first encapsulant 401 is placed into the molding cavity such that the first encapsulant 401 encapsulates the first semiconductor device regions 101, the first semiconductor die 313, and the second semiconductor die 315, the first encapsulant 401 may be cured in order to harden the first encapsulant 401 for optimum protection. While the exact curing process is dependent at least in part on the particular material chosen for the first encapsulant 401, in an embodiment in which molding compound is chosen as the first encapsulant 401, the curing could occur through a process such as heating the first encapsulant 401 to between about 100 ºC and about 200 ºC, such as about 125 ºC for about 60 sec to about 3000 sec, such as about 600 sec. Additionally, initiators and/or catalysts may be included within the first encapsulant 401 to better control the curing process.

However, as one having ordinary skill in the art will recognize, the curing process described above is merely an exemplary process and is not meant to limit the current embodiments. Other curing processes, such as irradiation or even allowing the first encapsulant 401 to harden at ambient temperature, may also be used. Any suitable curing process may be used, and all such processes are fully intended to be included within the scope of the embodiments discussed herein.

FIG. 4 further illustrates a thinning of the first encapsulant 401 in order to expose the first semiconductor die 313 and the second semiconductor die 315 for further processing. The thinning may be performed, e.g., using a mechanical grinding, chemical approaches, or chemical mechanical polishing (CMP) process whereby chemical etchants and abrasives are utilized to react and grind away the first encapsulant 401 so that the first semiconductor die 313 and the second semiconductor die 315 have been exposed and the first encapsulant 401 has a thickness of between about 100 μm and about 150 μm. As such, the first semiconductor die 313, and the second semiconductor die 315 may have a planar surface that is also coplanar with the first encapsulant 401. In another embodiment, the grinding may be omitted. For example, if the first semiconductor die 313 and the second semiconductor die 315 are already exposed after encapsulation, the grinding may be omitted.

Furthermore, while the CMP process described above is presented as one illustrative embodiment, it is not intended to be limiting to the embodiments. Any other suitable removal process may be used to thin the first encapsulant 401. For example, a series of chemical etches may be utilized. This process and any other suitable process may be utilized to planarize the first encapsulant 401, and all such processes are fully intended to be included within the scope of the embodiments.

Once ready the semiconductor wafer 100 may be singulated in order to separate the multitude of SoIC devices 400 into discrete components. In an embodiment the semiconductor wafer 100 may be singulated using, e.g., a sawing process, whereby a physical saw is utilized to cut through the semiconductor wafer 100 and first encapsulant 401. However, any suitable singulation process may be utilized.

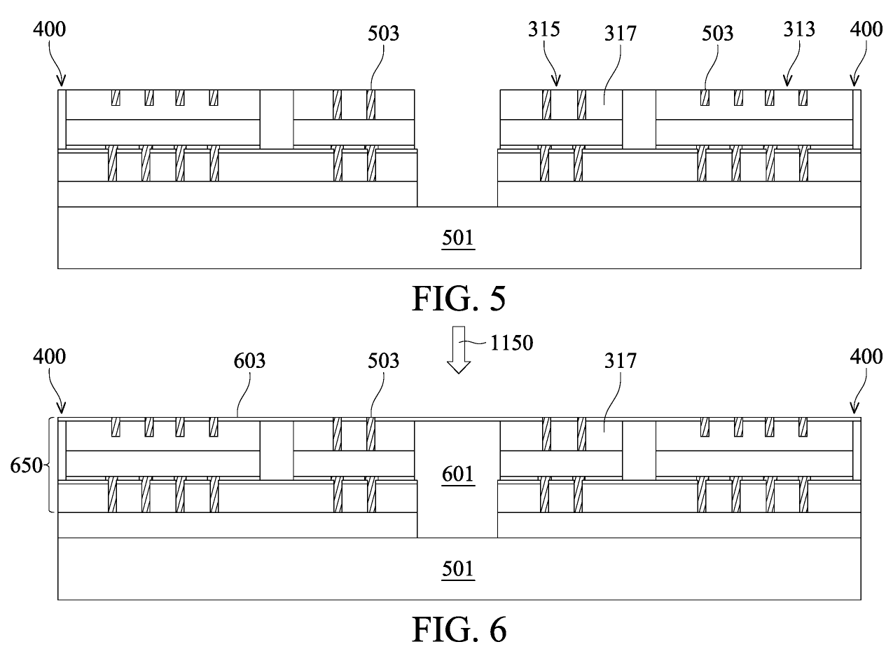

With reference now to FIG. 5, a multitude of the singulated SoIC devices 400 (for illustrative purposes two of the singulated SoIC devices 400 are depicted, however any suitable number of the SoIC devices 400 may be utilized) are attached to a first carrier substrate 501. In an embodiment the first carrier substrate 501 comprises, for example, silicon based materials, such as silicon, glass, or the like. However, any suitable materials may be utilized.

In an embodiment the SoIC devices 400 may be attached using either an adhesive (not separately illustrated in FIG. 5). In other embodiments the SoIC devices may be bonded using, e.g., an oxide-to-oxide bonding process. However, any suitable method of attaching the SoIC devices 400 to the first carrier substrate 501 may be utilized.

With reference now to FIG. 6, the SoIC devices 400 may be encapsulated with a second encapsulant 601 over the first carrier substrate 501. In an embodiment, the second encapsulant 601 may be placed over the SoIC devices 400 in a similar manner to the first encapsulant 401 and may be formed of similar materials. However, any suitable method and material may be utilized for the second encapsulant 601 for encapsulating the SoIC devices 400.

In an embodiment, FIG. 6 further illustrates a formation of a first passivation layer 603 over the SoIC devices 400 and the second encapsulant 601. In an embodiment, the formation of the first passivation layer 603 utilizes an etch back process 600. The etch back process 600 may be selective processes that etches the material of the second substrates 317 at a faster rate than a material of the second TSVs 503. The first passivation layer 603 may be formed over the second substrates 317, the second TSVs 503, and the second encapsulant 601. The first passivation layer 603 may be formed by a deposition process, such as by CVD, PVD, ALD, or the like. The first passivation layer 603 may comprise a dielectric material (e.g., silicon oxide, silicon nitride, silicon oxynitride, or the like), a polymer material (e.g., a polyimide, polybenzoxazole (PBO), polyimide, a benzocyclobuten (BCB) based polymer, or the like), or combinations thereof. Once formed, the first passivation layer 603 may be planarized to re-expose the second TSVs 503. However, any suitable process and material may be utilized in forming the first passivation layer 603. The encapsulated SoIC devices 400 with the first passivation layer 603 may be referred to as a first integrated device 650.

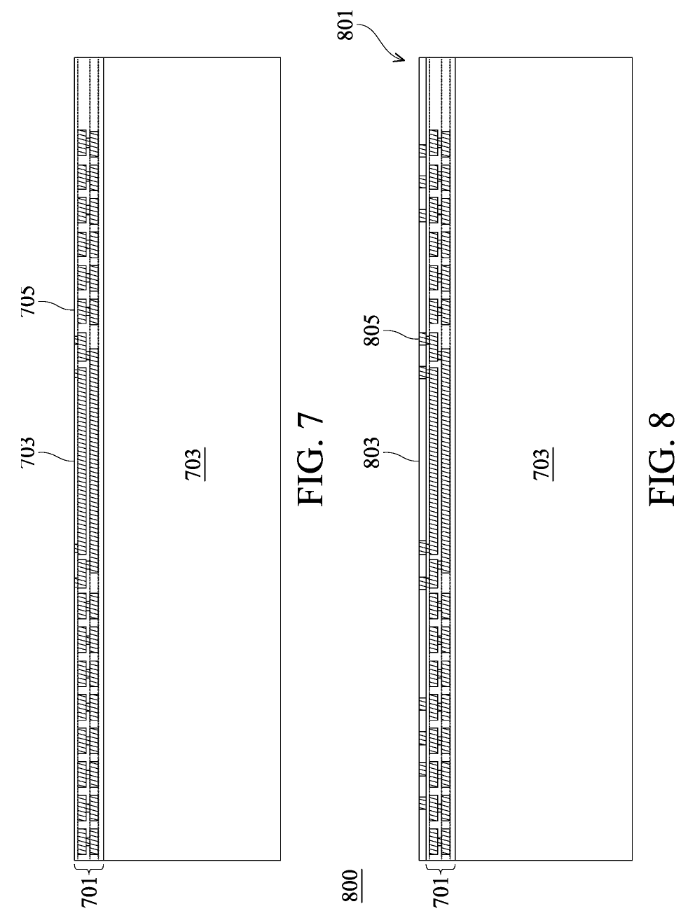

With reference now to FIG. 7, a first redistribution structure 701 is formed over a first support structure 703. In an embodiment, the first support structure 703 may comprise silicon, such as a bulk silicon, and in a particular embodiment may be a 12 inch silicon wafer. In an embodiment, the first redistribution structure 701 may include insulating layers 705, such as an inter-layer dielectric (ILD) and/or inter-metal dielectric layers (IMD) and conductive features (e.g., third metallization patterns 707) formed in the insulating layers. In an embodiment, some of the third metallization patterns 707 are dummy features utilized for thermal management while other portions of the third metallization patterns 707 are utilized for die to die connections (e.g., signal, power and ground connections) between the dies of adjacent SoIC devices 400. In an embodiment the third metallization patterns 707 may be formed using similar processes and materials as the first metallization layers 105, described above with respect to FIG. 1. However, any suitable methods and materials may be utilized.

In an embodiment the first support structure 703 is utilized not only for physical support but also to help remove thermal energy from the underlying devices. As such, in embodiments in which the first integrated device 650 comprises devices that utilize 1-2 kilowatts, the first support structure 703 may have a thickness of about 400 µm. However, in embodiments in which the first integrated device 650 comprises devices that utilize 4-5 kilowatts, the first support structure 703 may have a thickness of about 100 µm. Any suitable thickness may be utilized.

With reference now to FIG. 8, a formation of a first bridge bonding layer 801 is formed over the first redistribution structure 701. In an embodiment, the first bridge bonding layer 801 comprises a dielectric material 803 and first conductive connectors 805. Acceptable dielectric materials for the dielectric material 803 may include oxides such as silicon oxide or aluminum oxide; nitrides such as silicon nitride; carbides such as silicon carbide; the like; or combinations thereof such as silicon oxynitride, silicon oxycarbide, silicon carbonitride, silicon oxycarbonitride or the like. The dielectric material 803 may be formed by spin coating, lamination, chemical vapor deposition (CVD), or the like. The dielectric material 803 may then be patterned using, e.g., a photolithographic masking and etching process, although any suitable patterning process may be utilized. The patterning forms openings (not separately illustrated) exposing conductive portions of the first redistribution structure 701.

In an embodiment, a conductive material is formed in the openings and over the dielectric material 803. As an example to form the conductive material, a seed layer (not separately illustrated) may be formed over the dielectric material 803 and in the openings extending through the dielectric material 803. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. The conductive material may then be formed on the seed layer. The conductive material may be formed by plating, such as electroplating or electroless plating, or the like. The conductive material may comprise a metal, like copper, titanium, tungsten, aluminum, or the like.

In an embodiment, the first conductive connectors 805 are formed from the conductive material in the openings. In an embodiment, the first conductive connectors 805 are formed by removing excess material of the conductive material from a surface of the dielectric material 803 by, for example, a planarization process such as a chemical-mechanical polish (CMP), wherein the remaining conductive material in the openings of the dielectric material 803 forms the first conductive connectors 805. The first conductive connectors 805 provide an electrical contact point for connection to the first redistribution structure 701 to electrically couple to. In an embodiment, following the formation of the first bridge bonding layer 801 over the first redistribution structure 701 a first wafer bridge 800 is formed.

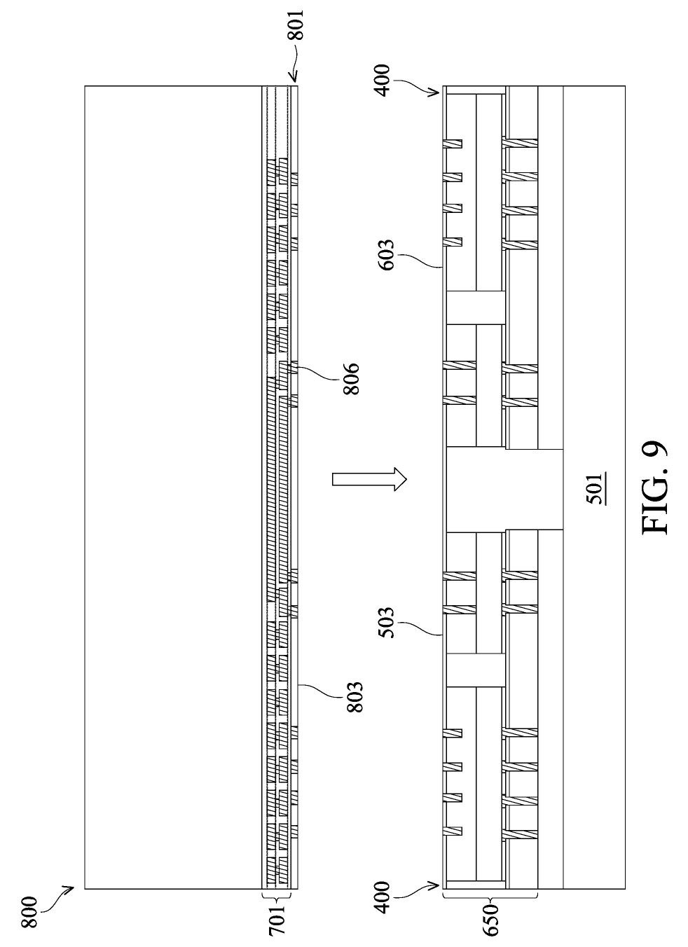

With reference now to FIG. 9, the first wafer bridge 800 is attached to the first integrated device 650. In an embodiment, the first wafer bridge 800 is attached to the first integrated device 650. In an embodiment, the first wafer bridge 800 may be attached to the SoIC devices 400 by bonding the first bridge bonding layer 801 to the first passivation layer 603 and the second TSVs 503. In an embodiment, the first bridge bonding layer 801 may be bonded by a dielectric-to-dielectric and metal-to-metal bonding process. In an embodiment the dielectric-to-dielectric and metal-to-metal bonding process may be performed as described above with respect to FIG. 3. However, any suitable bonding process may be utilized.

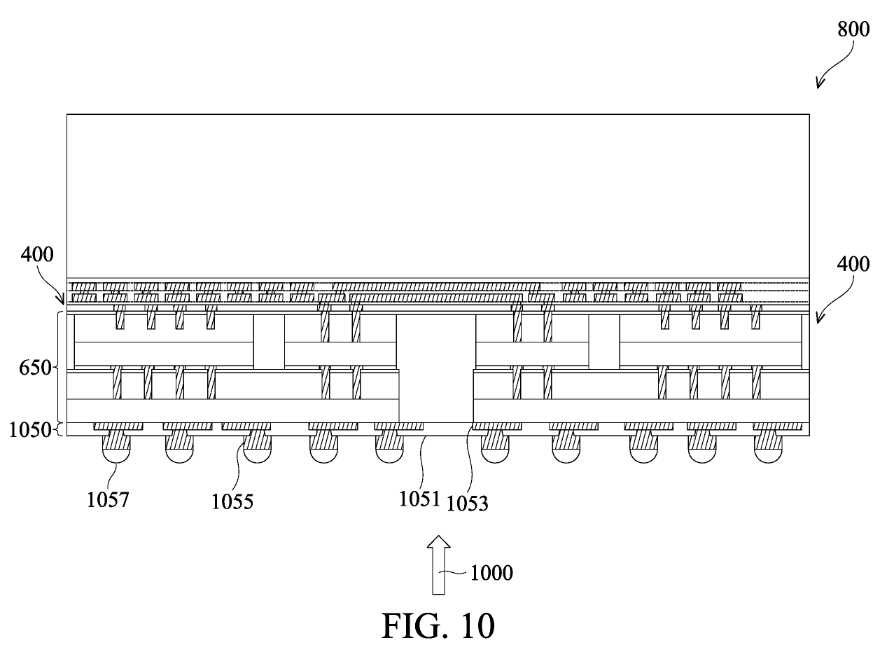

With reference now to FIG. 10, a first carrier removal process 1000 is performed to remove the first carrier substrate 501 and a bump out structure 1050 is formed over the SoIC devices 400 opposite the first wafer bridge 800. In an embodiment, the first carrier removal process 1000 may be a planarization process (in embodiments in which the first carrier substrate 501 is bonded) or simply removed (in embodiments in which the first carrier substrate 501 is attached with an adhesive). However, any suitable process may be utilized to remove the first carrier substrate 501.

In an embodiment, an exposed surface of the first integrated device 650 opposite the first wafer bridge 800 may serve as an interface location for a versatile bump out structure (e.g., bump out structure 1050). In an embodiment, the bump out structure 1050 includes a bump out dielectric layer 1051 and a bump out metallization pattern 1053. The bump out metallization pattern 1053 may also be referred to as a redistribution layer or a redistribution line. The bump out structure 1050 is shown as an example having one layer of metallization patterns. More dielectric layers and metallization patterns may be formed in the bump out structure 1050. If more dielectric layers and metallization patterns are to be formed, steps and processes discussed below may be repeated. However, any suitable processes and materials may be utilized to form the bump out structure 1050. In some embodiments, the bump out structure 1050 may be omitted entirely.

In an embodiment, the bump out metallization pattern 1053 includes conductive elements extending along the major surface of the first planar bottom surface to physically and electrically couple the first integrated device 650. As an example to form the bump out metallization pattern 1053, a seed layer is formed over the first planar bottom surface of the first integrated device 650. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the bump out metallization pattern 1053. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. The combination of the conductive material and underlying portions of the seed layer form the bump out metallization pattern 1053. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching.

In an embodiment, the bump out dielectric layer 1051 is deposited over the bump out metallization pattern 1053 and along the first planar bottom surface. In some embodiments, the bump out dielectric layer 1051 is formed of a photo-sensitive material such as PBO, polyimide, BCB, or the like, which may be patterned using a lithography mask. The bump out dielectric layer 1051 may be formed by spin coating, lamination, CVD, the like, or a combination thereof. The bump out dielectric layer 1051 is then patterned. The patterning forms openings exposing portions of the bump out metallization patterns 1053. The patterning may be by an acceptable process, such as by exposing and developing the bump out dielectric layer 1051 to light when the bump out dielectric layer 1051 is a photo-sensitive material or by etching using, for example, an anisotropic etch.

Following the patterning of the bump out dielectric layer 1051, under bump metallizations (UBMs) 1055 are formed for external connection to the first integrated device 650 through the bump out structure 1050. The UBMs 1055 have bump portions on and extending along the major surface of the bump out dielectric layer 1051, and have via portions extending through the bump out dielectric layer 1051 to physically and electrically couple the bump out metallization pattern 1053. As a result, the UBMs 1205 are electrically coupled to the first integrated device 650. The UBMs 1055 may be formed of the same material as the bump out metallization pattern 1053. In some embodiments, the UBMs 1055 have a different size than the bump out metallization pattern 1053.

Further, in an embodiment, conductive connectors 1057 are formed on the UBMs 1055. The conductive connectors 1057 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 1207 may include a conductive material such as solder, copper, aluminum, gold, nickel, silver, palladium, tin, the like, or a combination thereof. In some embodiments, the conductive connectors 1057 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 1057 comprise metal pillars (such as a copper pillar) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

By utilizing the first wafer bridge 800 as described herein, the overlying structural support can be further utilized and transformed into a powerful, functional layer for wafer level system integration that provides high, energy efficient performance (EEP). This allows systems to be scaled up for computing power aggregation, all without the need for a special substrate or a special pin out for system power distribution.

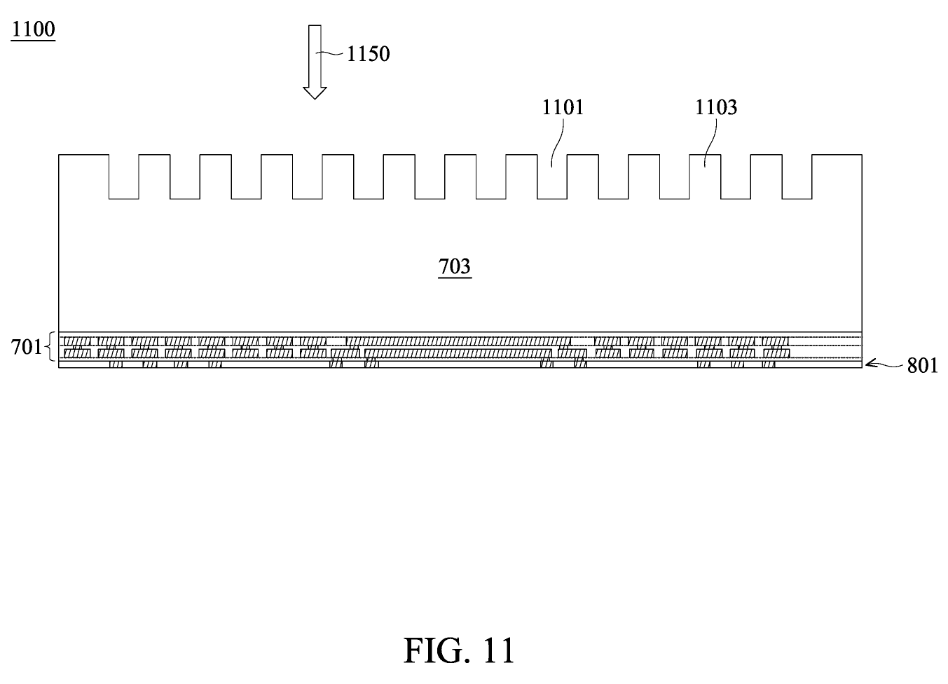

With reference now to FIG. 11, in another embodiment a formation of a second wafer bridge 1100 is depicted. In an embodiment, the second wafer bridge 1100 may be formed in a similar manner and from similar materials as the first wafer bridge 800 and may similarly comprise the first redistribution structure 701 and the first bridge bonding layer 801. However, any suitable process and materials may be utilized in forming the second wafer bridge 1100.

In this embodiment, however, further processing is performed on the first support structure 703 to form one or more cavities 1101 compatible with additional cooling capabilities (e.g., air or liquid cooling) in the first support structure 703. In an embodiment, the one or more cavities 1101 may be formed in the first support structure 703 by a removal process 1150, which removes material from the first support structure 703. The removal of material from the first support structure 703 forms the one or more cavities 1101 within the first support structure 703 with remaining portions of material of the first support structure 703 forming micropillars 1103 between the one or more cavities 1101. In an embodiment, the micropillars 1103 may serve multiple functions, such as providing structural support for subsequent structures and interrupting a flow of cooling fluid (not separately illustrated in FIG. 11) through the cavity 1101 to improve cooling capabilities of the first support structure 703.

In an embodiment, the removal process 1150 may be an etching process, such as a reactive ion etch (RIE), neutral beam etch (NBE), the like, or a combination thereof. The etching process may be anisotropic. In an embodiment, a pattern of the micropillars 1103 may be formed during the removal process 1150 by any suitable method. For example, the micropillars 1103 may be formed using one or more photolithography processes to mask areas of the first support structure 703 that are not removed during the removal process 1150. In another embodiment, the cavity 1101 and the micropillars 1103 may be formed by the removal process 1150 where the removal process 1150 is a mechanical removal processes such as a drilling process. However, any suitable process may be used for the removal process 1150 in forming the cavity 1101 and the micropillars 1103.

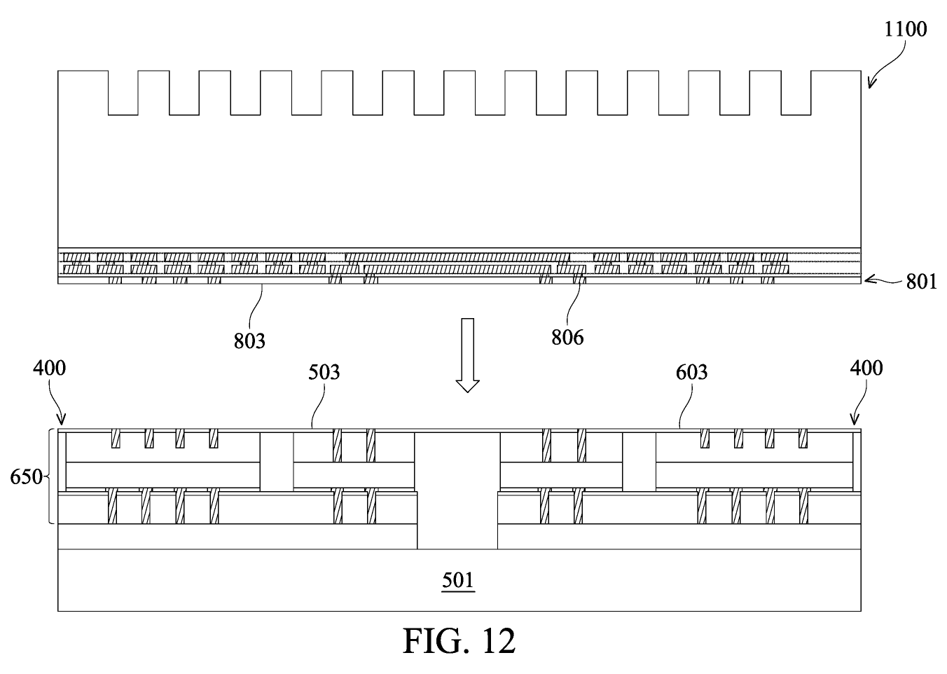

With reference now to FIG. 12, the second wafer bridge 1100 is attached to the first integrated device 650. In an embodiment, the second wafer bridge 1100 may be attached to the first integrated device 650 in a similar manner as the first wafer bridge 800 is attached to the first integrated device 650, such as using a dielectric-to-dielectric and metal-to-metal bonding process. However, any suitable process may be utilized to attach the second wafer bridge 1100 to the first integrated device 650.

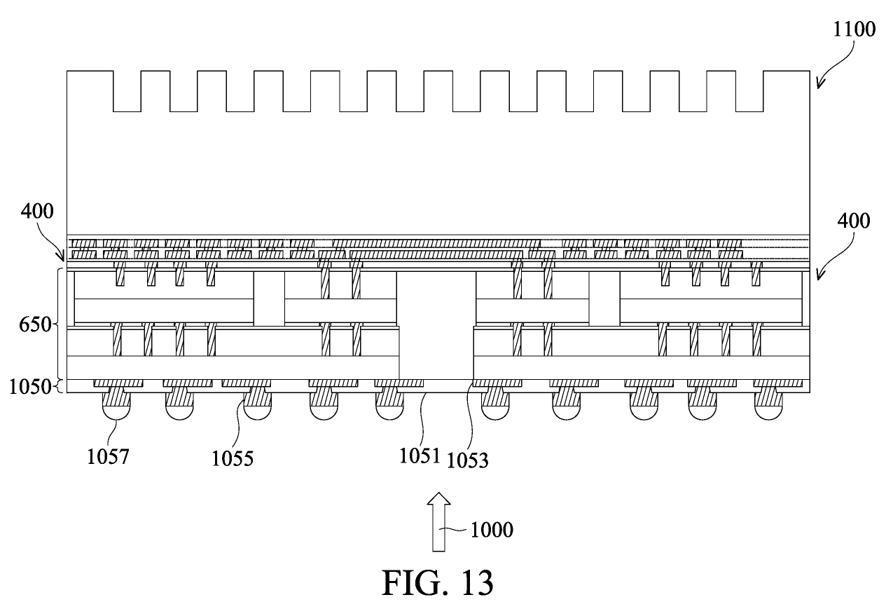

With reference now to FIG. 13, the first carrier removal process 1000 may be performed to remove the first carrier substrate 501 and the bump out structure 1050 may be formed over the first integrated device 650 opposite the second wafer bridge 1100. In other embodiments, formation of the bump out structure 1050 may be omitted and an exposed surface of the first integrated device 650 may act as the interface location for a versatile bump out structure.

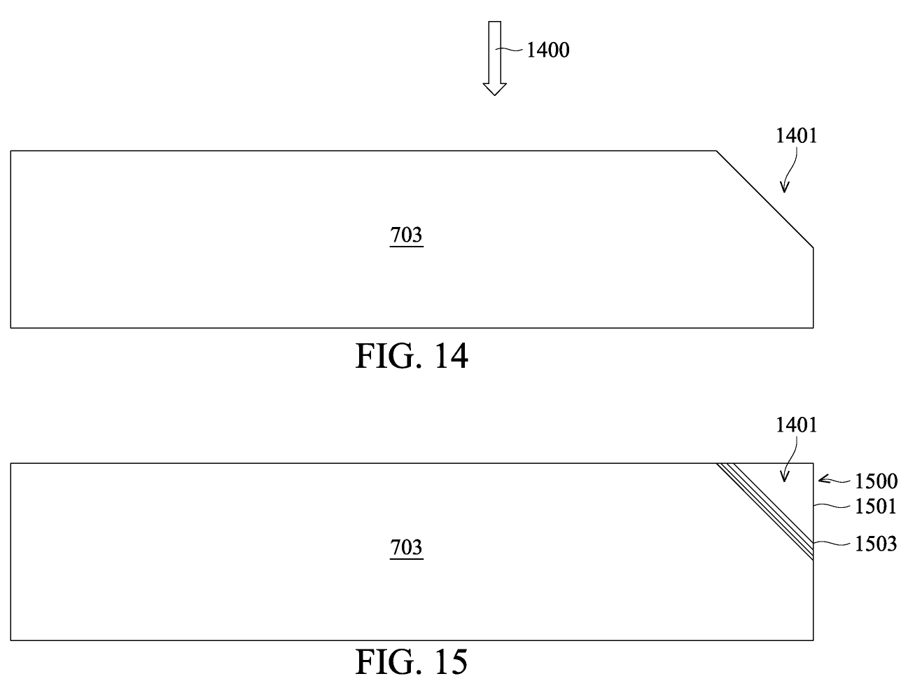

With reference now to FIG. 14, with respect to yet another embodiment, a first patterning process 1400 is performed on the first support structure 703 in preparation of forming a first optical interface structure 1500 (not illustrated in FIG. 14, but illustrated and described further below in FIG. 15). In an embodiment, the first patterning process 1400 patterns the first support structure 703 using, using, e.g., one or more photolithographic masking and etching processes. In an embodiment, the first patterning process 1400 trims a corner of the first support structure 703 such that following the first patterning process 1400 the first support structure 703 has a tapered edge 1401.

With reference now to FIG. 15, the first optical interface structure 1500 is formed over the tapered edge 1401 following the first patterning process 1400. In an embodiment, the first optical interface structure 1500 includes a first insulating material 1501 and a first optical component 1503. In an embodiment, the first optical component 1503 is a reflective structure formed parallel to the tapered edge 1401 of the first support structure 703. In an embodiment, the reflective structure may be deposited using processes such as sputtering, plating, evaporation, or plasma-enhanced chemical vapor deposition (PECVD), or the like. The reflective structure may comprise a metal such as copper, titanium, titanium nitride, aluminum, aluminum nitride, gold, gold nitride, aluminum copper, or the like. In another embodiment, the first optical component 1503 is a distributed Bragg reflector (DBR) formed by alternating layers of a first refractive index layer (not separately illustrated) and a second refractive index layer (not separately illustrated) over the tapered edge 1401 of the first support structure 703, the first refractive index layer having a different refractive index than the second refractive index layer. It should be noted that the first optical component 1503 may be any suitable optical component for transmitting and/or redirecting an optical signal from the subsequently attached first integrated device 650.

The first insulating material 1501 may be silicon oxide, silicon nitride, germanium oxide, germanium nitride, combinations of these, or the like. The first insulating material 1501 may be formed using a deposition method such as CVD, ALD, PVD, combinations of these, or the like. In an embodiment, the first insulating material 1501 may be formed over the tapered edge 1401 of the first support structure 703. In an embodiment, a planarization process may be performed on the first insulating material 1501 to facilitate subsequent processing.

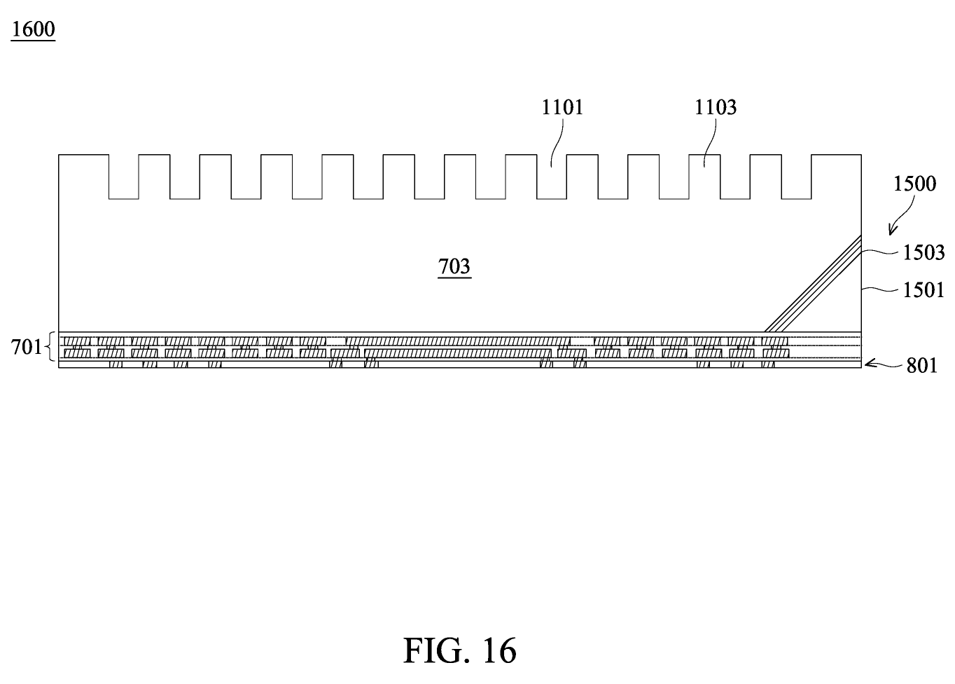

With reference now to FIG. 16, a formation of a third wafer bridge 1600 with the first optical interface structure 1500 is depicted. In an embodiment, the third wafer bridge 1600 may be formed in a similar manner and from similar materials as the first wafer bridge 800 (with the addition of the first optical interface structure 1500) and may similarly comprise the first redistribution structure 701 and the first bridge bonding layer 801. However, any suitable process and materials may be utilized in forming the second wafer bridge 1100.

Optionally, if desired further processing may be performed on the first support structure 703 to form the one or more cavities 1101 and the micropillars 1103 in the first support structure 703 to facilitate cooling capabilities within the third wafer bridge 1600. The one or more cavities 1101 and the micropillars 1103 may be formed in a similar manner as discussed above, however, any suitable process may be utilized in forming the one or more cavities 1101 and the micropillars 1103. Additionally, in an embodiment the cavity 1101 and the micropillars 1103 may be omitted.

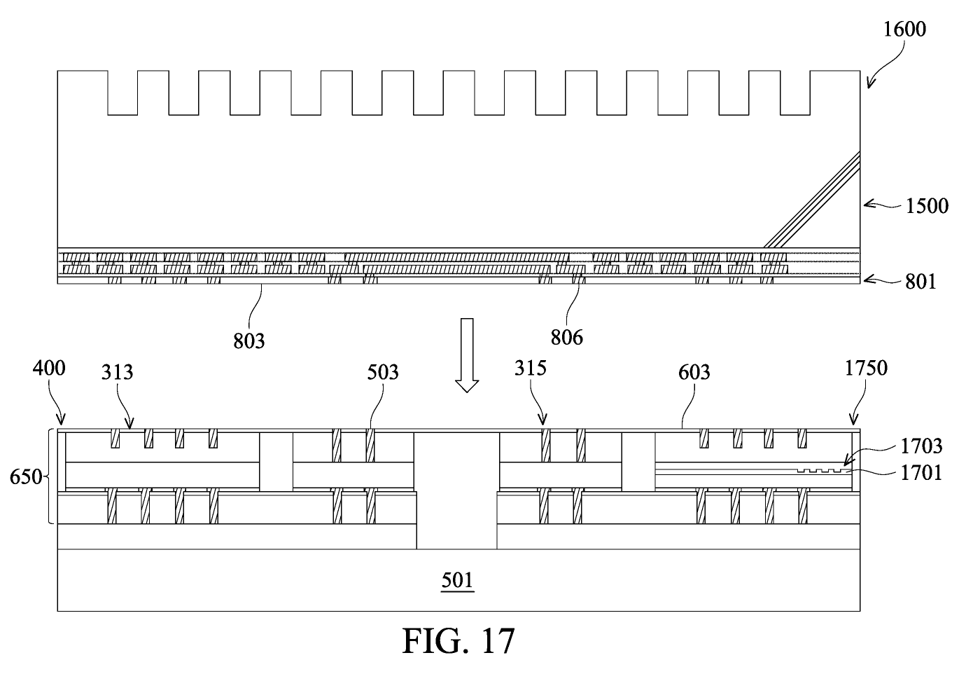

With reference now to FIG. 17, the third wafer bridge 1600 is attached to the first integrated device 650. In an embodiment, the third wafer bridge 1600 may be attached to the first integrated device 650 in a similar manner as the first wafer bridge 800 is attached to the first integrated device 650, such as by using a dielectric-to-dielectric and metal-to-metal bonding process. However, any suitable process may be utilized to attach the third wafer bridge 1600 to the first integrated device 650.

In other embodiments, the first redistribution structure 701 may be omitted and the first bridge bonding layer 801 may be omitted. In such an embodiment where the first bridge bonding layer 801 is omitted, the first insulating material 1501 may be utilized to form a dielectric-to-dielectric bond with the first passivation layer 603 to attach the third wafer bridge 1600 to the first integrated device 650.

In this embodiment which includes the first optical interface structure 1500, one or more of the first semiconductor dies 313 or the second semiconductor dies 315 of the SoIC devices 400 within the first integrated device 650 may be photonic integrated circuits (PIC) dies positioned to transmit and receive signals from the first optical interface structure 1500. In an embodiment where the first semiconductor die 313 or the second semiconductor die 315 of the SoIC device 400 is a PIC die 1750, the PIC die 1750 may comprise a first active layer 1701 of second optical components 1703. In an embodiment, the second optical components 1703 may include such components as optical waveguides (e.g., ridge waveguides, rib waveguides, buried channel waveguides, diffused waveguides, etc.), couplers (e.g., grating couplers, edge couplers, etc.), directional couplers, optical modulators (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like. However, any suitable second optical components 1703 may be used.

Further, in an embodiment where the first integrated device 650 includes the PIC die 1750, the first semiconductor device regions 101 of the semiconductor wafer 100 of the associated SoIC device 400 may be an electronic integrated circuit (EIC) that interfaces with the PIC die 1750. Further, in an embodiment where the first integrated device 650 includes the PIC die 1750, the PIC die 1750 may be positioned within the first integrated device 650 such that after the attachment of the third wafer bridge 1600 to the first integrated device 650 the second optical components 1703 within the PIC die 1750 (e.g., a grating coupler) may interface with the first optical interface structure 1500 within the third wafer bridge 1600 to facilitate the transmission of optical signals into and out of the first integrated device 650.

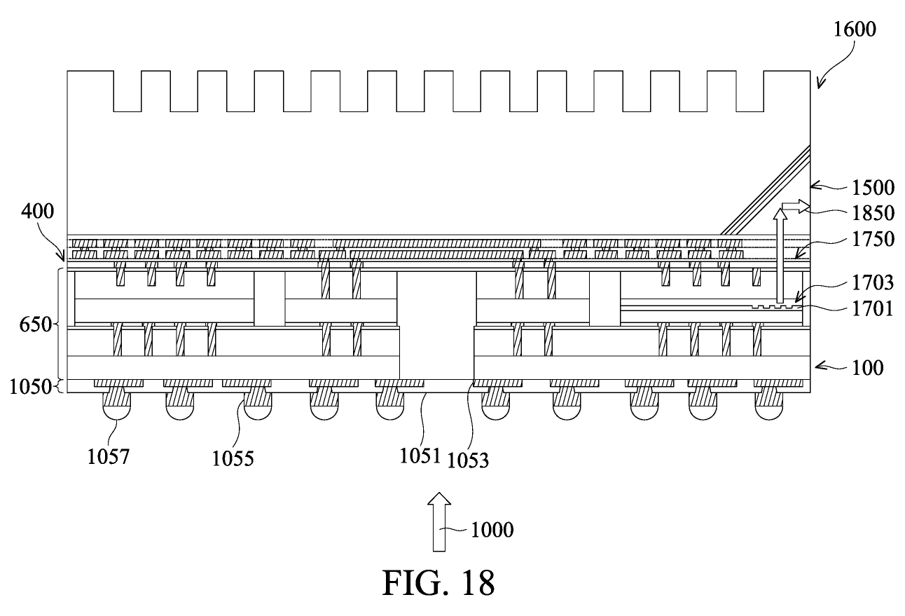

With reference now to FIG. 18, the first carrier removal process 1000 may be performed to remove the first carrier substrate 501 and the bump out structure 1050 may be formed over the first integrated device 650 opposite the third wafer bridge 1600. Further depicted in FIG. 18 is a transmission of optical signals 1850 from the second optical components 1703 of the PIC die 1750 out of the first integrated device 650 through the third wafer bridge 1600. In this embodiment, the first optical interface structure 1500 of the third wafer bridge 1600 may be utilized to facilitate the transmission of the optical signals 1850 out of a side edge of the third wafer bridge 1600. Further, the first optical interface structure 1500 of the third wafer bridge 1600 may also be utilized to transmit optical signals (not separately illustrated) from outside of the first integrated device 650 towards the second optical components 1703 of the PIC die 1750 through the third wafer bridge 1600.

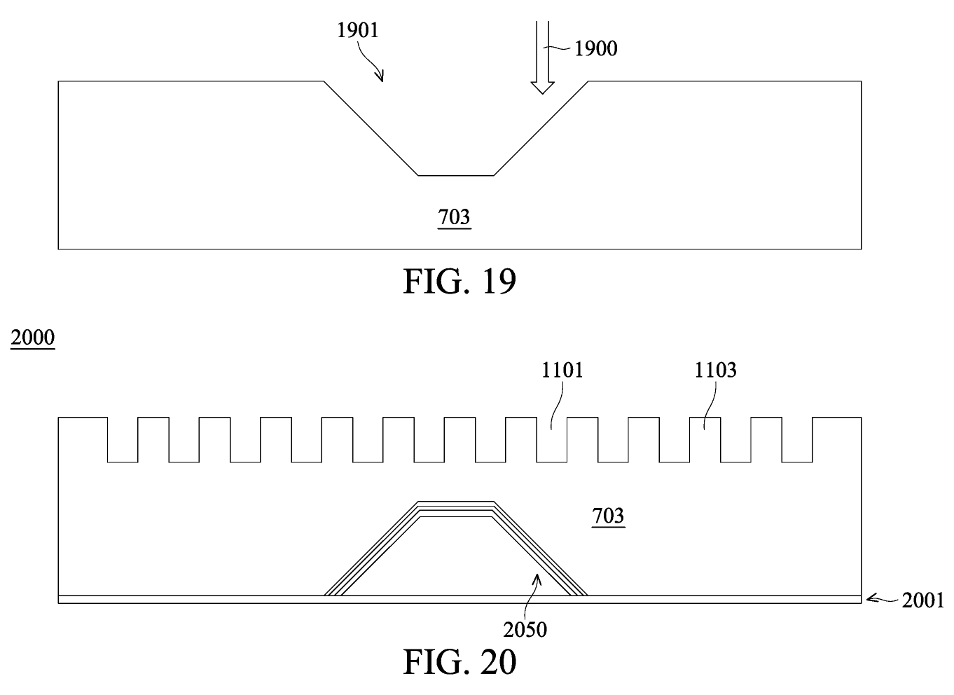

With reference now to FIG. 19, there is illustrated yet another embodiment which utilizes optical components. In this embodiment a second patterning process 1900 is performed on the first support structure 703 in preparation for forming a second optical interface structure 2050 (not illustrated in FIG. 19, but illustrated in FIG. 20). In an embodiment, the second patterning process 1900 may be performed in a similar manner as the first patterning process 1400, such as a photolithographic masking and etching process. However, any suitable patterning process and process parameters may be utilized in patterning the first support structure 703.

In this embodiment, the second patterning process 1900 is performed such that a first recess 1901 is formed in the first support structure 703. In a particular embodiment, the first recess 1901 is formed to be in the shape of a trapezoid. However, any suitable shape may be formed for the first recess 1901 to facilitate the formation of the second optical interface structure 2050.

With reference now to FIG. 20, a formation of a fourth wafer bridge 2000 is depicted. In an embodiment, the fourth wafer bridge 2000 may be formed in a similar manner and from similar materials as the third wafer bridge 1600 (depicted above with respect to FIG. 16). However, in embodiments in which the fourth wafer bridge 2000 is utilized to optically bridge, but not electrically bridge, the various devices, so the first redistribution structure 701 and the first bridge bonding layer 801 are not formed. If desired, however, the first redistribution structure 701 and the first bridge bonding layer 801 may be formed and used in order to electrically bridge the various devices. However, any suitable materials and processes may be utilized.

In an embodiment, the second optical interface structure 2050 is formed in the first recess 1901. The second optical interface structure 2050 may be formed in a similar manner and from similar processes to form similar structures as the first optical interface structure 1500. However, any suitable materials, processes, and structures may be utilized for the second optical interface structure 2050.

Optionally, and as illustrated, further processing may be performed on the first support structure 703 to form the one or more cavities 1101 and the micropillars 1103 in the fourth wafer bridge 2000 to facilitate cooling capabilities within the fourth wafer bridge 2000. The cavity 1101 and the micropillars 1103 may be formed in a similar manner as discussed above with respect to FIG. 11.

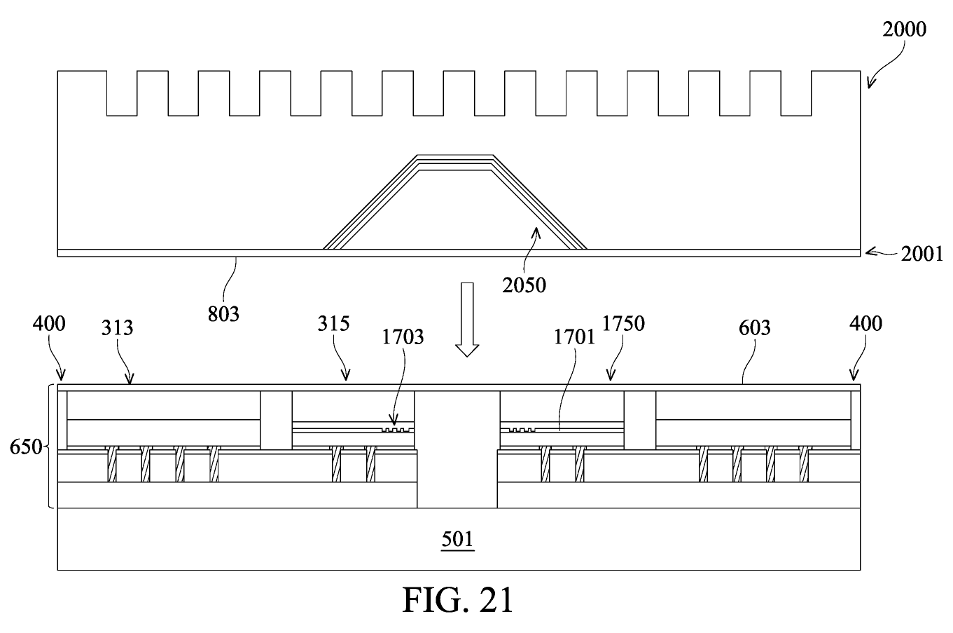

In an embodiment where the first bridge bonding layer 801 is omitted from the fourth wafer bridge 2000, a second bridge bonding layer 2001 may be utilized. In an embodiment, the second bridge bonding layer 2001 comprises the dielectric material 803 without the first conductive connectors 805. The second bridge bonding layer 2001 may be formed over the second optical interface structure 2050 and may be utilized to attach the fourth wafer bridge 2000 to the first integrated device 650 (not illustrated in FIG. 20 but illustrated and described further below with respect to FIG. 21). However, any suitable process and materials may be utilized in forming the fourth wafer bridge 2000.

With reference now to FIG. 21, the fourth wafer bridge 2000 is attached to the first integrated device 650. In an embodiment where the first redistribution structure 701 is omitted from the fourth wafer bridge 2000 the dielectric material 803 of the second bridge bonding layer 2001 may be utilized to form a dielectric-to-dielectric bond with the first passivation layer 603 of the first integrated device 650. The dielectric-to-dielectric bond may be formed between the dielectric material 803 of the second bridge bonding layer 2001 to the first passivation layer 603 in a similar manner as discussed above with respect to the dielectric-to-dielectric bond formed between the dielectric material 803 of the first bridge bonding layer 801 to the first passivation layer 603. In an embodiment in which the bump out structure 1050 is present, the fourth wafer bridge 2000 may be attached to the first integrated device 650 in a similar manner as the first wafer bridge 800 is attached to the first integrated device 650. However, any suitable process may be utilized to attach the fourth wafer bridge 2000 to the first integrated device 650.

Further, in an embodiment, one or more of the first semiconductor dies 313 or the second semiconductor dies 315 in each of the SoIC devices 400 within the first integrated device 650 may be the PIC die 1750. The PIC die 1750 may comprise the first active layer 1701 of the second optical components 1703 as described above. Further, in an embodiment where the first integrated device 650 includes the PIC die 1750 in more than one of the SoIC devices 400, the PIC die 1750 may be positioned within the first integrated device 650 such that after the attachment of the fourth wafer bridge 2000 to the first integrated device 650 the second optical components 1703 within each of the PIC dies 1750 may interface with the second optical interface structure 2050 within the fourth wafer bridge 2000 to facilitate the transmission of the optical signals 1850 between the PIC dies 1750 in each of the SoIC devices 400 across the first integrated device 650.

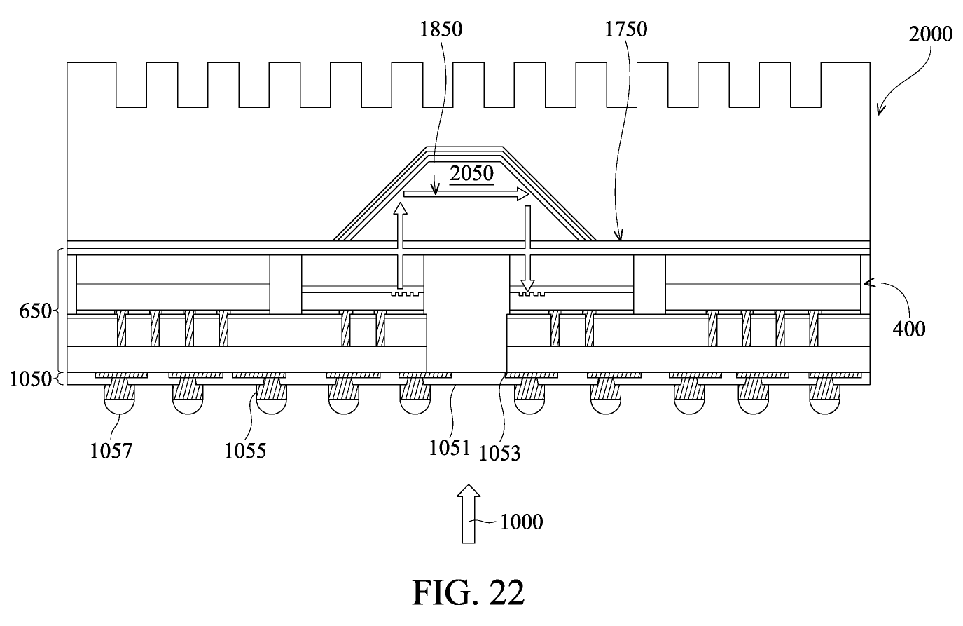

With reference now to FIG. 22, the first carrier removal process 1000 may be performed to remove the first carrier substrate 501 and the bump out structure 1050 may be formed over the first integrated device 650 opposite the fourth wafer bridge 2000. In some embodiments, formation of the bump out structure 1050 may be omitted. Further in this embodiment, the second optical interface structure 2050 embedded within the fourth wafer bridge 2000 may act as a redistribution structure for the optical signals 1850 between the PIC dies 1750 within the various SoIC devices 400.

For example, in this embodiment the optical signals 1850 may be transmitted from one of the PIC dies 1750 and is reflected by the second optical interface structure 2050. The second optical interface structure 2050 then redirects the optical signals 1850 out of the second optical interface structure 2050 and to another one of the PIC dies 1750. As such, the second optical interface structure 2050 acts as an optical bridge between the various PIC dies 1750.

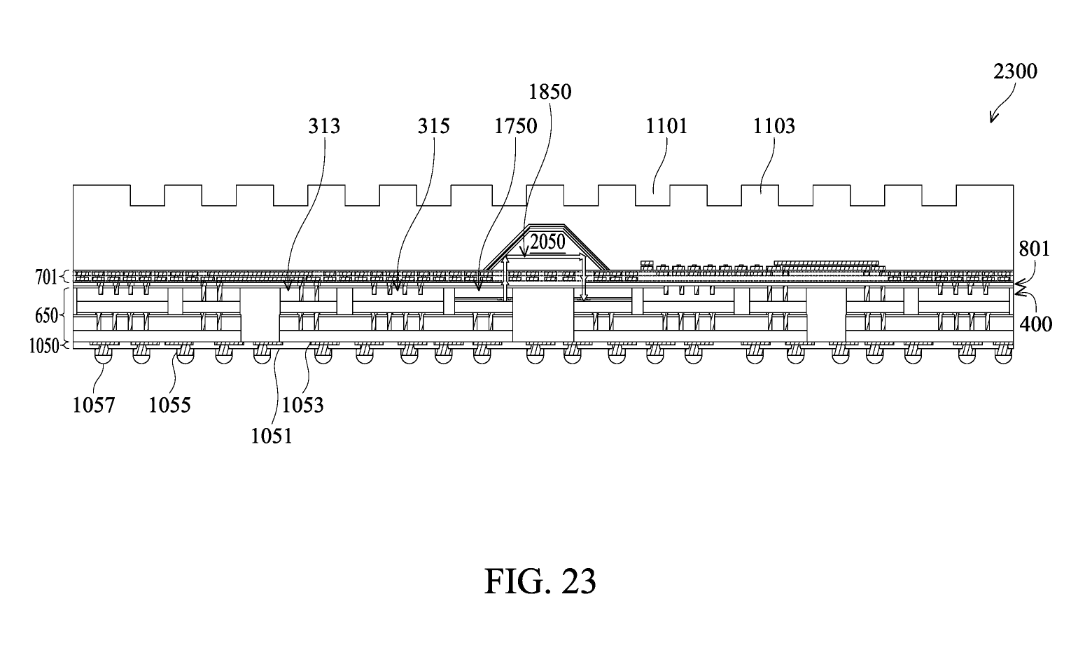

With reference now to FIG. 23, a fifth wafer bridge 2300 is attached to the first integrated device 650. In this embodiment, the fifth wafer bridge 2300 may comprise the first redistribution structure 701, the first bridge bonding layer 801, the second optical interface structure 2050 and, optionally, the one or more cavities 1101 with the micropillars 1103. In an embodiment, the first redistribution structure 701, the first bridge bonding layer 801, the second optical interface structure 2050, and the one or more cavities 1101 with the micropillars 1103 may be formed in a similar manner and from similar materials as discussed above. However, any suitable material and processes may be utilized to form the first redistribution structure 701, the first bridge bonding layer 801, the second optical interface structure 2050, and the one or more cavities 1101 with the micropillars 1103.

FIG. 23 further depicts the first integrated device 650 as comprising four of the SoIC devices 400. The number of the SoIC devices 400 is merely illustrative and the first integrated device 650 may comprise any number of SoIC devices 400 to form the desired functional device. Additionally, FIG. 23 depicts several of the SoIC devices 400 as comprising the first semiconductor die 313, the second semiconductor die 315, and the PIC die 1750 over the semiconductor wafer 100 of the associated SoIC device 400. The number of semiconductor dies within each of the SoIC devices 400 is merely illustrative and each of the SoIC devices 400 may comprise any number of semiconductor dies performing a variety of functions to form the desired functional device. The fifth wafer bridge 2300 comprises the first redistribution structure 701 and the second optical interface structure 2050 to facilitate interconnectivity between the varying devices of the different SoIC devices 400 within the first integrated device 650. Additionally, the cavity 1101 and the micropillars 1103 within the fifth wafer bridge 2300 facilitate cooling to accommodate thermal requirements associated with upward scaling of the first integrated device 650.

FIG. 23 further illustrates the placement of a versatile bump out interface, such as the bump out structure 1050. In an embodiment the bump out structure 1050 may be formed as described above with respect to FIG. 10, such as forming the bump out metallization pattern 1053, the UBMs 1055, and the conductive connectors 1057. However, any suitable materials and processes may be utilized.

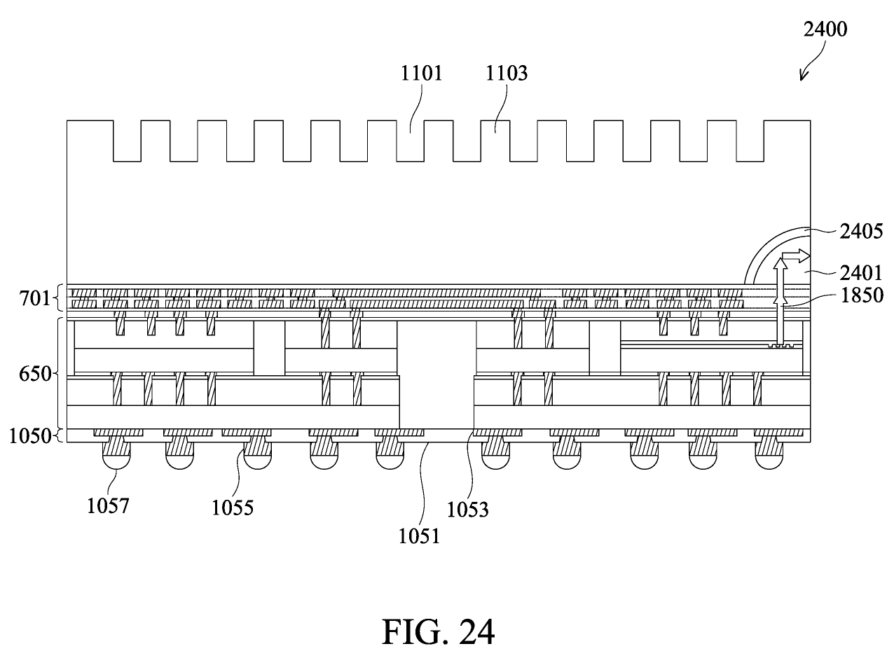

With reference now to FIG. 24, a sixth wafer bridge 2400 is attached to the first integrated device 650. In this embodiment, the sixth wafer bridge 2400 comprises a polymer-based material 2401 instead of the first insulating material 1501 (as described above with respect to FIG. 15) in order to help with the singulation process. In a particular embodiment the polymer-based material may be a polymer such as polyimide, BCB, or epoxy, combinations of these, or the like. However, any suitable material may be utilized.

To form the sixth wafer bridge 2400 with the polymer-based material 2401, the first support structure 703 may first be patterned as described above with respect to FIG. 14. For example, the first support structure 703 may be patterned using a photolithographic masking and etching process. In this embodiment, however, the recess 2403 may be formed not only in the straight shape but may also be rounded in shape. Any suitable shape may be utilized.

Once the recess 2403 has been formed into the desired shape, a first layer 2405 may be formed along the sidewall of the first support structure 703. In an embodiment the first layer 2405 may be formed by treating the exposed surface using, e.g., a mixture of argon and oxygen (O₂) to oxidize the exposed surface, or CVD/PVD for oxide deposition (followed by planarization). However, any suitable process may be used.

Once the first layer 2405 has been formed, the polymer-based material 2401 may be placed in order to fill the recess 2403. In an embodiment the polymer-based material 2401 may be placed using a spin coating process, a lamination process, a chemical vapor deposition (CVD) process, combinations of these, or the like. If desired, once the polymer-based material 2401 has been deposited, excess material of the polymer-based material 2401 outside of the recess may be removed using, e.g., a planarization process. However, any suitable process may be utilized.

By using the recess 2403, the first layer 2405, and the polymer-based material 2401, a dual curve prism may be formed. In particular, in an embodiment the prism may have an x-curvature radius of about 296.4 µm and may also have a y-curvature radius of about 592.6 µm and a mode field diameter of about 8.85 µm (for transmission) and about 9.54 µm (for receiving). Such dimensions allow for a transmission efficiency of about 99.7% (for transmission) and about 97% (for receiving) (for a system with a polymer waveguide height of about 80 µm, a polymer waveguide length of about 423 µm, a silicon height of about 750 µm, and a silicon index of about 3.5). However, any suitable dimensions may be utilized.

Once the polymer-based material 2401 has been formed, the sixth wafer bridge 2400 may be bonded to the first integrated device 650 and the bump out structure 1050 may be formed. In an embodiment the bonding may be performed as described above with respect to FIG. 9 (e.g., a dielectric-to-dielectric and metal-to-metal bonding process), while the bump out structure 1050 may be formed as described above with respect to FIG. 10, such as forming the bump out metallization pattern 1053, the UBMs 1055, and the conductive connectors 1057. However, any suitable materials and processes may be utilized.

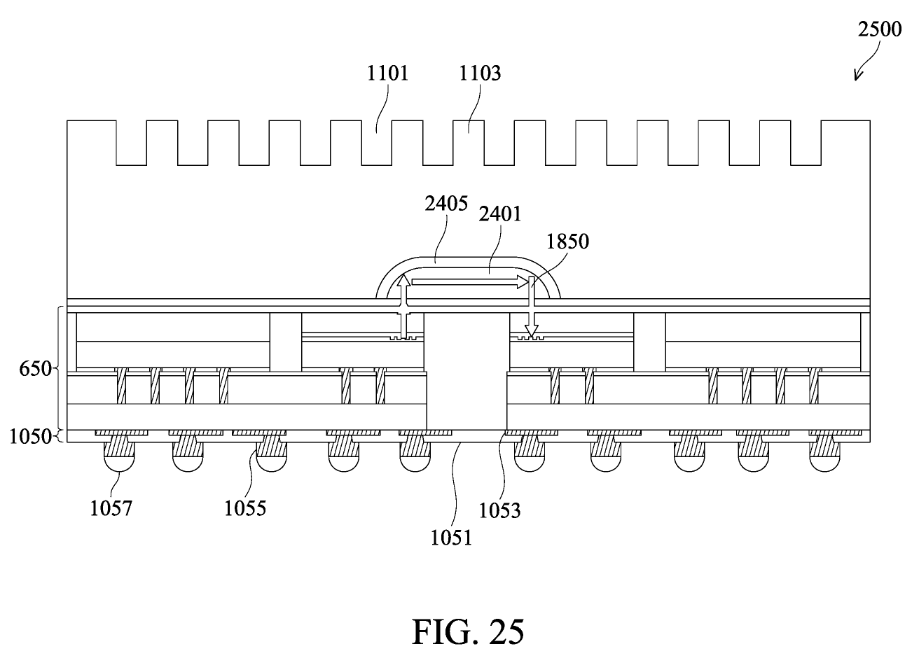

With reference now to FIG. 25, a seventh wafer bridge 2500 is formed and attached to the first integrated device 650. In this embodiment, the seventh wafer bridge 2500 may be similar to the fourth wafer bridge 2000 (described above with respect to FIG. 20) but which uses the processes and materials to incorporate the first layer 2405 and the polymer-based material 2401 as described above with respect to FIG. 24. As such, a dual curvature prism can be formed to both receive and transmit and, therefore, bridge optical signals from one device to another.

Once the seventh wafer bridge 2500 has been formed, the seventh wafer bridge 2500 may be bonded to the first integrated device 650 and the bump out structure 1050 may be formed. In an embodiment the bonding may be performed as described above with respect to FIG. 9 (e.g., a dielectric-to-dielectric and metal-to-metal bonding process), while the bump out structure 1050 may be formed as described above with respect to FIG. 10, such as forming the bump out metallization pattern 1053, the UBMs 1055, and the conductive connectors 1057. However, any suitable materials and processes may be utilized.

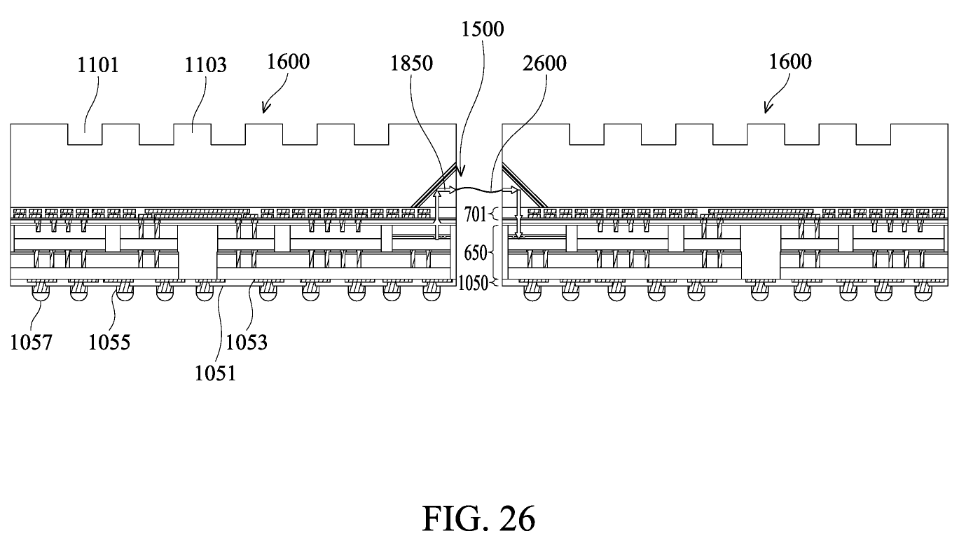

With reference now to FIG. 26, an embodiment is illustrated in which one or more optical fibers 2600 are attached to the third wafer bridge 1600 (described above with respect to FIGS. 16-18). In an embodiment each of the one or more optical fibers 2600 may comprise a core material such as glass surrounded by one or more cladding materials. Optionally, a surrounding cover material may be used to surround the outer cladding material in order to provide additional protection. In some embodiments the optical fibers 2600 may be 100 meters long, although any suitable length may be utilized.

In this embodiment the one or more optical fibers 2600 may be positioned in order to transmit and receive optical signals through the first optical interface structure 1500 within the third wafer bridge 1600. In particular embodiments the one or more optical fibers 2600 are connected using, e.g., a ferrule (not separately illustrated in FIG. 26). However, any suitable connection may be utilized.

FIG. 26 additionally illustrates that, even though the one or more optical fibers 2600 may be attached to any suitable device, in some particular embodiments, the one or more optical fibers 2600 may be attached to another third wafer bridge 1600. In this embodiment the one or more optical fibers 2600 may be attached with, e.g., another ferrule, and works to bridge the optical signals 1850 from a first one of the first integrated devices 650 to a second one of the first integrated devices 650.

Finally, it should be noted that all of the features and structures of all of the described wafer bridge structures and various devices within the various SoIC devices may be interchanged, combined, or omitted based on the interconnectivity and thermal requirements of the overall wafer device structure.

By utilizing the wafer bridge structures as described herein, the overlying structural support can be further utilized and transformed into a powerful, functional layer for wafer level system integration with a high, energy efficient performance (EEP). This allows systems to be sustainably scaled up by fiber or wafer scale fabrication for computing power aggregation, all without the need for a special substrate or a special pin out for system power distribution.

In accordance with an embodiment, a method of manufacturing a semiconductor device includes: bonding a first die and a second die to a third die, the first die comprising a first optical device; encapsulating the first die and the second die with an encapsulant; and bonding a bridge to the first die and the second die on an opposite side from the third die, wherein an optical component of the bridge is aligned to transmit and receive optical signals to and from the first optical device. In an embodiment the method further includes encapsulating a fourth die with the first die, the second die, and the third die, wherein the second die comprises a second optical device. In an embodiment after the bonding the bridge the optical component of the bridge is aligned to transmit and receive optical signals to and from the second optical device. In an embodiment the method further includes encapsulating a fourth die with the first die, wherein the bridge further comprises a first redistribution structure, the first redistribution structure electrically connecting the first die to the fourth die. In an embodiment the method further includes attaching at least one optical fiber to the optical component. In an embodiment the bridge comprises one or more recesses separated by one or more micropillars. In an embodiment the optical component of the bridge is a dual curve prism. In an embodiment the method further includes

In accordance with another embodiment, a method of manufacturing a semiconductor device includes: forming a first optical component in a recess of a substrate; and bonding a first die and a second die to a semiconductor wafer; encapsulating the first die and the second die after the bonding; singulating the semiconductor wafer, wherein a second optical component within the first die is aligned with the first optical component. In an embodiment after the bridging a third die comprises a third optical component, the second optical component being aligned with the first optical component. In an embodiment the method further includes attaching an optical fiber aligned with the first optical component. In an embodiment the method further includes attaching the optical fiber to a second optical component in a second bridge, the second optical component aligned with a third optical component of a third die bonded to the second bridge. In an embodiment the third die is encapsulated with a fourth die. In an embodiment the bridging the first die and the second die electrically bridges the second die with a third die, the third die also bonded to the substrate. In an embodiment the substrate comprises one or more recesses separated by micropillars.

In yet another embodiment, a semiconductor device includes: a first die; a second die encapsulated with the first die; and a bridge bonded to both the first die and the second die, the bridge including: an electrical connection between the first die and the second die; and a first optical component aligned with a second optical component of the first die. In an embodiment the semiconductor device further includes an optical fiber attached to the bridge and aligned with the first optical component. In an embodiment the first optical component optically connects the second die to a third die. In an embodiment the first optical component comprises a dual curve prism. In an embodiment the bridge comprises one or more cavities separated by one or more micropillars. In an embodiment the first die is a die-to-die die.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a first die and a second die bonded to a third die, the first die comprising a first optical device;
an encapsulant encapsulating the first die and the second die; and
a bridge bonded to the first die and the second die on an opposite side of the first die from the third die, wherein an optical component of the bridge is aligned with the first optical device.

2. The semiconductor device of claim 1, further comprising a fourth die encapsulated with the first die, the second die, and the third die, the fourth die comprising a second optical device, wherein the optical component of the bridge is aligned to transmit and receive optical signals to and from the second optical device.

3. The semiconductor device of claim 2, further comprising a fifth die encapsulated with the first die, wherein the bridge further comprises a first redistribution structure, the first redistribution structure electrically connecting the first die to the fifth die.

4. The semiconductor device of claim 1, wherein the optical component of the bridge comprises mirrors.

5. The semiconductor device of claim 1, wherein the optical component of the bridge is a dual curve prism.

6. The semiconductor device of claim 1, wherein the bridge comprises one or more recesses separated by one or more micropillars.

7. The semiconductor device of claim 1, further comprising at least one optical fiber attached to the bridge.

8. A semiconductor device comprising:
a first optical component in a recess of a substrate; and
a first die and a second die bonded to a third die; and
an encapsulant encapsulating the first die and the second die, wherein a second optical component within the first die is aligned with the first optical component.

9. The semiconductor device of claim 8, further comprising a third optical component in the second die, the second optical component being aligned with the first optical component.

10. The semiconductor device of claim 8, further comprising an optical fiber attached to the substrate.

11. The semiconductor device of claim 10, wherein the optical fiber is aligned with a second optical component in a second bridge, the second optical component aligned with a third optical component of a fourth die bonded to the second bridge.

12. The semiconductor device of claim 11, wherein the fourth die is encapsulated with a fifth die.

13. The semiconductor device of claim 8, wherein the substrate comprises electrical connections that electrically bridges the second die with a fourth die.

14. The semiconductor device of claim 8, wherein the substrate comprises one or more recesses separated by micropillars.

15. A semiconductor device comprising:
a first die;
a second die encapsulated with the first die; and
a bridge bonded to both the first die and the second die, the bridge comprising:
an electrical connection between the first die and the second die; and
a first optical component aligned with a second optical component of the first die.

16. The semiconductor device of claim 15, further comprising an optical fiber attached to the bridge and aligned with the first optical component.

17. The semiconductor device of claim 15, wherein the first optical component optically connects the first die to a third die.

18. The semiconductor device of claim 15, wherein the first optical component comprises a dual curve prism.

19. The semiconductor device of claim 15, wherein the bridge comprises one or more cavities separated by one or more micropillars.

20. The semiconductor device of claim 15, wherein the first die is a die-to-die die.
